(19) United States
(12) Patent Application Publication
(10) Pub. No.: US 2024/0203946 A1
(43) Pub. Date: Jun. 20, 2024

(54) SEMICONDUCTOR CHIP, SEMICONDUCTOR PACKAGE, AND WAFER DICING METHOD

(71) Applicant: SAMSUNG ELECTRONICS CO., LTD., SUWON-SI (KR)

(72) Inventors: Junyeong HEO, Suwon-si (KR); Unbyoung KANG, Daejeon (KR); Sera LEE, Daejeon (KR); Jihoon JUNG, Suwon-si (KR)

(21) Appl. No.: 18/537,997

(22) Filed: Dec. 13, 2023

(30) Foreign Application Priority Data
Dec. 16, 2022 (KR) 10-2022-0177329

(51) Int. Cl. H01L 25/065; H01L 21/78; H01L 23/00; H01L 23/48; H01L 29/06

(52) U.S. Cl. CPC H01L 25/0657; H01L 21/78; H01L 23/481; H01L 24/16; H01L 24/32; H01L 24/73; H01L 29/0657; H01L 2224/16145; H01L 2224/16225; H01L 2224/32145; H01L 2224/73204; H01L 2225/06565; H01L 2225/06568

(57) ABSTRACT

A semiconductor chip includes a semiconductor substrate having an active surface and an inactive surface opposite the active surface. A semiconductor device layer is disposed on the active surface. A modified region is positioned on an entirety of a lateral side surface of the semiconductor substrate.

### CROSS-REFERENCE TO RELATED APPLICATIONS

This application claims priority under 35 U.S.C. § 119 to Korean Patent Application No. 10-2022-0177329, filed on Dec. 16, 2022 in the Korean Intellectual Property Office, the disclosure of which is incorporated by reference in its entirety herein.

### 1. TECHNICAL FIELD

The present inventive concept relates to a semiconductor chip, a semiconductor package, and a wafer dicing method.

### 2. DISCUSSION OF RELATED ART

Semiconductor chips are manufactured by forming a plurality of semiconductor chips together on a semiconductor substrate, such as a wafer. The semiconductor chips are then separated from each other by performing a singulation process thereon.

In addition, as the electronics industry has advanced, manufacturing methods have been developed in which a plurality of semiconductor packages including a plurality of semiconductor chips may be formed together using a semiconductor substrate such as a wafer, or semiconductor packages are formed together by attaching the same to a support substrate and then performing a singulation process thereon to increase the productivity of the manufacturing process.

### SUMMARY

Embodiments of the present inventive concept provide a semiconductor chip, a semiconductor package, and a wafer dicing method, whereby the yield of semiconductor devices is increased.

In addition, the objectives to be solved by embodiments of the present inventive concept are not limited to the above-mentioned one, and other objectives may be clearly understood by those skilled in the art from the description below.

Embodiments of the present inventive concept provide a semiconductor chip, a semiconductor package, and a wafer dicing method as below to achieve the technical objective.

According to an embodiment of the present inventive concept, a semiconductor chip includes a semiconductor substrate having an active surface and an inactive surface opposite the active surface. A semiconductor device layer is disposed on the active surface. A modified region is positioned on an entirety of a lateral side surface of the semiconductor substrate.

According to an embodiment of the present inventive concept, a semiconductor package includes a first substrate. A first chip structure is arranged on the first substrate. A first bump structure electrically connects the first substrate to the first chip structure. The first chip structure comprises at least one semiconductor chip. The at least one semiconductor chip comprises a semiconductor substrate and a semiconductor device layer. A modified region is positioned over an entirety of a lateral side surface of the semiconductor substrate. The modified region comprises a region that the semiconductor substrate is modified by laser as the semiconductor substrate is cut in a vertical direction by laser grooving.

According to an embodiment of the present inventive concept, a wafer dicing method includes preparing a wafer having a plurality of device formation regions and a scribe lane region defining the plurality of device formation regions. The wafer is cut on a cutting surface of the wafer positioned along the scribe lane region. The wafer is separated into a plurality of semiconductor chips by a laser grooving process using a laser. A modified region is formed in the wafer by the laser. The modified region is formed over an entirety of the cutting surface of the wafer.

### BRIEF DESCRIPTION OF THE DRAWINGS

Embodiments of the present inventive concept will be more clearly understood from the following detailed description taken in conjunction with the accompanying drawings in which:

FIG. 1 is a schematic cross-sectional view of a semiconductor package according to an embodiment of the present inventive concept;

FIG. 2A is a schematic cross-sectional view of an embodiment of a semiconductor chip of the semiconductor package of FIG. 1 according to an embodiment of the present inventive concept;

FIG. 2B is an enlarged cross-sectional view of region AA of FIG. 2A according to an embodiment of the present inventive concept;

FIG. 3A is a schematic cross-sectional view of the semiconductor chip of the semiconductor package of FIG. 1 according to an embodiment of the present inventive concept;

FIG. 3B is an enlarged cross-sectional view of region BB of FIG. 3A according to an embodiment of the present inventive concept:

FIG. 4 is a schematic flowchart of a semiconductor package manufacturing method according to an embodiment of the present inventive concept; and

FIGS. 5 to 12 are cross-sectional views for describing a semiconductor package manufacturing method according to embodiments of the present inventive concept.

### DETAILED DESCRIPTION OF EMBODIMENTS

Hereinafter, embodiments of the present inventive concept will be described more fully with reference to the accompanying drawings. In the drawings, like elements are labeled like reference numerals and repeated description thereof may be omitted for economy of description.

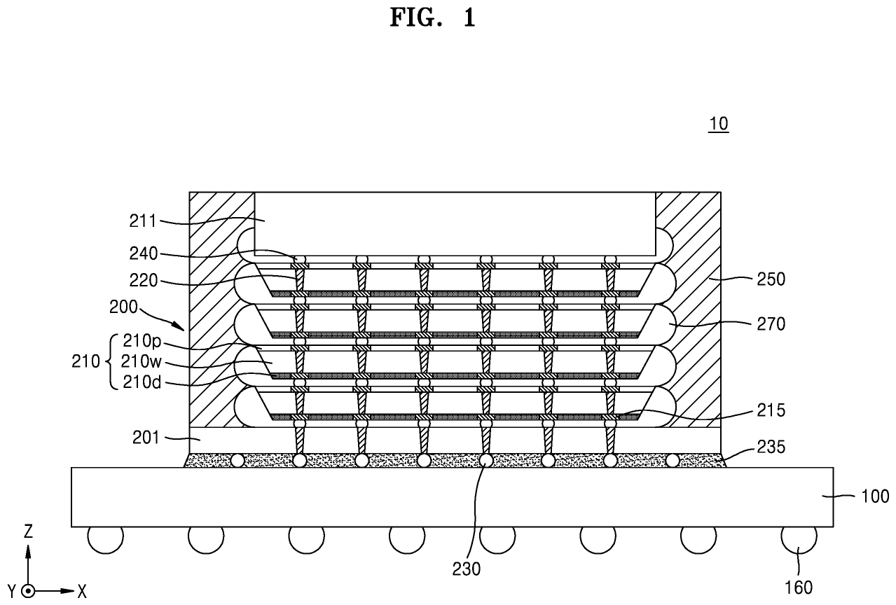

FIG. 1 is a schematic cross-sectional view of a semiconductor package according to an embodiment of the present inventive concept.

Referring to FIG. 1, a semiconductor package 10 may include a first substrate 100, a first external connection terminal 160, and a first chip structure 200.

The first substrate 100 may be disposed below the first chip structure 200 (e.g., in the Z-axis direction) and is electrically connected to the first chip structure 200. In an embodiment, the first substrate 100 may be a ceramic substrate, a printed circuit board (PCB), an organic substrate, or an interposer substrate. However, embodiments of the present inventive concept are not necessarily limited thereto. Also, in some embodiments, the first substrate 100 may have a redistribution structure manufactured through a redistribution process.

The first external connection terminal 160 may be located on a lower surface of the first substrate 100. In an embodiment, the first external connection terminal 160 may be electrically connected to an external device, such as a mother board, a PCB, or a package substrate. In an embodiment, the first external connection terminal 160 may be electrically connected to wiring patterns formed in the first substrate 100 through a substrate pad attached to the lower surface of the first substrate 100. The first external connection terminal 160 may electrically and physically connect the semiconductor package 10 to an external device on which the semiconductor package 10 is mounted. In an embodiment, the first external connection terminal 160 may include a conductive material, for example, at least one compound selected from solder, tin (Sn), silver (Ag), copper (Cu), and aluminum (Al). However, embodiments of the present inventive concept are not necessarily limited thereto.

The first chip structure 200 may be disposed on an upper surface of the first substrate 100 (e.g., in the Z-axis direction). In an embodiment, the first chip structure 200 may be mounted on the first substrate 100 in a flip chip method through a first bump structure 230 such as a micro bump.

In an embodiment, the first bump structure 230 may include a conductive material, for example, at least one material selected from solder, tin (Sn), silver (Ag), copper (Cu), and aluminum (Al). In embodiments, an underfill material layer 235 surrounding the first bump structure 230 may be disposed between the first chip structure 200 and the first substrate 100 (e.g., in the Z-axis direction). In an embodiment, the underfill material layer 235 may include, for example, an epoxy resin formed by a capillary under-fill method. However, embodiments of the present inventive concept are not necessarily limited thereto. For example, in some embodiments a molding member may be directly filled in a gap between the first chip structure 200 and the first substrate 100 through a molded under-fill process. In this embodiment, the underfill material layer 235 may be omitted.

The first chip structure 200 may include at least one semiconductor chip. For example, in an embodiment the semiconductor chip may include a logic semiconductor chip or a memory semiconductor chip. The logic semiconductor chip may include, for example, a microprocessor such as a central processing unit (CPU), a graphics processing unit (GPU), or an application processor (AP), an analog device, or a digital signal processor, and the memory semiconductor chip may include, for example, a volatile memory chip such as Dynamic Random Access Memory (DRAM) or Static Random Access Memory (SRAM), or Phase-change Random Access Memory (PRAM), magnetoresistive random access memory (MRAM), ferroelectric random access memory (FeRAM), or resistive random access memory (RRAM). However, embodiments of the present inventive concept are not necessarily limited thereto.

The first chip structure 200 may include a plurality of semiconductor chips stacked in one direction. In the drawings below, an X-axis direction and a Y-axis direction indicate directions parallel to the upper surface or the lower surface of the first chip structure 200, and the X-axis direction and the Y-axis direction may be perpendicular to each other. A Z-axis direction may indicate a direction perpendicular to the upper surface or the lower surface of the first chip structure 200. For example, the Z-axis direction may be a direction perpendicular to an X-Y plane. Also, in the following drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

In an embodiment as shown in FIG. 1, the first chip structure 200 may include a plurality of semiconductor chips stacked in a vertical direction Z. In an embodiment, the first chip structure 200 may include different types of semiconductor chips. For example, as shown in an embodiment of FIG. 1, the first chip structure 200 may include a base chip 201 arranged at a lowermost end of the first chip structure 200, a semiconductor chip 210, and a top layer semiconductor chip 211. However, embodiments of the present inventive concept are not necessarily limited thereto.

In an embodiment, the base chip 201 may be mounted on the first substrate 100, a plurality of semiconductor chips 210 may be mounted on the base chip 201, and the top layer semiconductor chip 211 may be mounted at an uppermost end of the first chip structure 200 above the plurality of semiconductor chips 210.

In an embodiment, the base chip 201 may include logic devices. Accordingly, the base chip 201 may be a logic chip. The base chip 201 may be disposed under the semiconductor chips 210 (e.g., in the Z-axis direction) to integrate signals of the semiconductor chips 210 and transfer them to the outside (e.g., external devices), and also to transfer signals and power from the outside to the semiconductor chips 210. Accordingly, the base chip 201 may be referred to as a buffer chip or a control chip. The semiconductor chips 210 may include a plurality of memory devices, for example, DRAM devices. The semiconductor chips 210 may be referred to as memory chips or core chips.

In an embodiment, the semiconductor chips 210 may be stacked on the base chip 201 through pad-to-pad bonding, bonding using a bonding member, or bonding using an anisotropic conductive film (ACF).

In an embodiment, the semiconductor chip 210 may be mounted on the base chip 201 through a second bump structure 240 in a flip chip manner. In addition, the semiconductor chips 210 may be mounted on one another through the second bump structure 240 in a flip chip method.

In an embodiment, the semiconductor chip 210 may be a High Bandwidth Memory (HBM) DRAM chip, and may be semiconductor chips used in an HBM package. The semiconductor chip 210 may include a first through electrode 220 formed therein and extending through the first through electrode 220. The plurality of semiconductor chips 210 stacked in the vertical direction Z may be electrically connected to each other through the first through electrode 220. In an embodiment, the semiconductor chip 210 may be mounted on the first substrate 100 such that a semiconductor device layer 210d faces the first substrate 100.

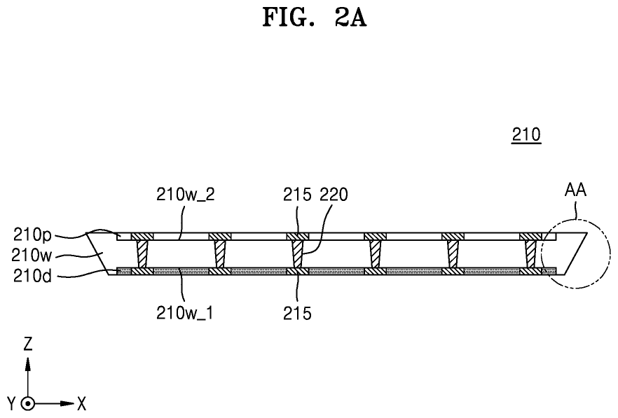

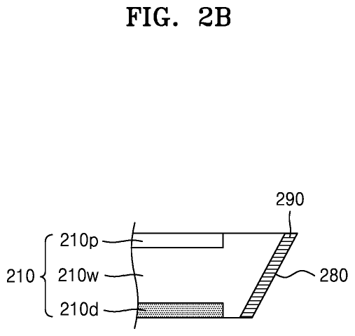

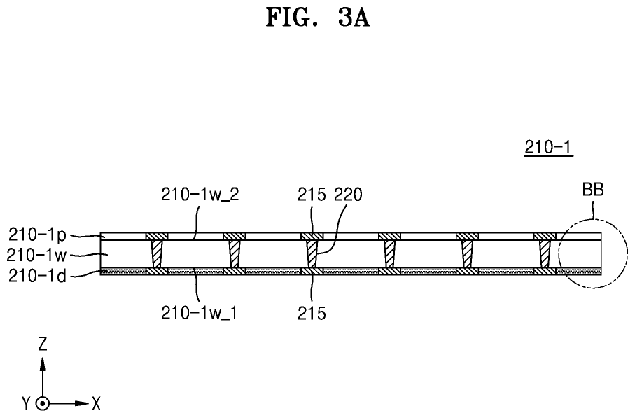

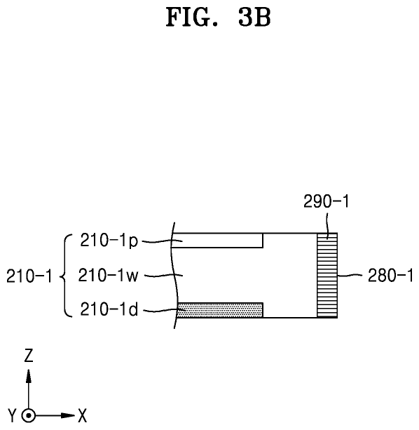

The semiconductor chip 210 may further include the semiconductor device layer 210d, a semiconductor substrate 210w, a passivation layer 210p, and a connection pad 215. This will be described in detail with reference to FIGS. 2A to 3B.

In an embodiment, an underfill material layer surrounding the second bump structure 240 may be disposed between the base chip 201 and the semiconductor chips 210 stacked on the base chip 201. In an embodiment, the underfill material layer may include, for example, an epoxy resin formed by a capillary under-fill method. However, embodiments of the present inventive concept are not necessarily limited thereto. For example, in some embodiments a first molding member 250 may be directly filled in a gap between the base chip 201 and the semiconductor chips 210 through a molded under-fill process. In this embodiment, the underfill material layer may be omitted. Similarly, an underfill material layer surrounding the second bump structure 240 may be disposed between the semiconductor chips 210 that are stacked on one another.

The first bump structure 230 disposed on a lower surface of the base chip 201 may be electrically connected to the first through electrode 220 formed in the base chip 201. Also, the first through electrode 220 formed in the semiconductor chips 210 may be electrically connected to the second bump structure 240. The first through electrode 220 may pass through (e.g., pass entirely through) each of the base chip 201 and the semiconductor chips 210. The first through electrode 220 may extend in the vertical direction Z. The first through electrode 220 may have a tapered shape in which a horizontal width thereof decreases or increases as a vertical level increases. For example, as shown in an embodiment of FIG. 1, the horizontal width of the first through electrode 220 may increase as a vertical level increases. Some of the first through electrodes 220 may have a pillar shape. In an embodiment, the first through electrodes 220 may include through silicon vias (TSV).

The top layer semiconductor chip 211 may be a chip that is stacked at an uppermost end of the first chip structure 200. In an embodiment, the top layer semiconductor chip 211 may not include first through electrodes therein. In an embodiment, the top layer semiconductor chip 211 may have a greater vertical thickness than the semiconductor chips 210.

The first chip structure 200 may further include a connection film 270. The connection film 270 may be formed between the plurality of semiconductor chips 210 and/or between the base chip 201 and the semiconductor chip 210. For example, the connection film 270 may be between the plurality of semiconductor chips 210 and/or between the base chip 201 and the semiconductor chip 210. In an embodiment, the connection film 270 may include an insulating polymer. For example, the connection film 270 may include a non-conductive film (NCF). However, embodiments of the present inventive concept are not necessarily limited thereto.

In an embodiment, as a space formed between the semiconductor chips 210 in the vertical direction Z widens, a length of a portion of the connection film 270 protruding in a horizontal direction (X or Y), such as, the fillet length, may decrease.

The first chip structure 200 may further include the first molding member 250 surrounding the base chip 201, the semiconductor chips 210, and the top layer semiconductor chip 211. In an embodiment, the first molding member 250 may include a thermosetting resin such as epoxy resin, a thermoplastic resin such as polyimide, or a resin including these with a reinforcing material such as an inorganic filler, such as Ajinomoto Build-up Film (ABF), FR-4, BT, etc. However, embodiments of the present inventive concept are not necessarily limited thereto. The first molding member 250 may be formed of a molding material such as epoxy molding compound (EMC) or a photosensitive material such as photoimageable encapsulant (PIE). In some embodiments, a portion of the first molding member 250 may include an insulating material such as a silicon oxide layer, a silicon nitride layer, or a silicon oxynitride layer.

Although in FIG. 1 the number of stacked semiconductor chips 210 is illustrated as four, the first chip structure 200 is not necessarily limited thereto, and the first chip structure 200 may include one semiconductor chip 210 or two, three or five or more stacked semiconductor chips 210 in some embodiments.

In addition, although a step is formed on a side surface of the semiconductor chip 210 in FIG. 1, such as the semiconductor chip 210 having a trapezoidal shape is illustrated, as described below with reference to FIGS. 2A and 2B, this is only an embodiment and embodiments of the present inventive concept are not necessarily limited to the trapezoidal shape. As illustrated in FIGS. 3A and 3B, the shape of the semiconductor chip 210 may be a shape without a step on the side surface thereof, such as a shape in which a vertical cross-section of the semiconductor chip 210 is a rectangle.

FIG. 2A is a schematic cross-sectional view of an embodiment of a semiconductor chip of the semiconductor package 10 of FIG. 1. FIG. 2B is an enlarged cross-sectional view of region AA of FIG. 2A. Hereinafter, the semiconductor chip 210 of the semiconductor package 10 of FIG. 1 will be described in detail. In addition, a repeated description of details provided with reference to FIG. 1 may be omitted for economy of description.

Referring to FIGS. 2A and 2B, the semiconductor chip 210 may include the semiconductor substrate 210w, the semiconductor device layer 210d, the passivation layer 210p, the connection pad 215, and a modified region 290. The semiconductor substrate 210w may have an active surface 210w_1 and an inactive surface 210w_2 opposite to the active surface 210w_1 (e.g., in the Z-axis direction). The active surface 210w_1 is a surface of the semiconductor substrate 210w adjacent to the semiconductor device layer 210d, and the semiconductor device layer 210d may be formed on (e.g., formed directly thereon in the Z-axis direction) the active surface 210w_1. The inactive surface 210w_2 is a surface opposite to the active surface 210w_1 (e.g., in the Z-axis direction), and the passivation layer 210p may be formed on (e.g., formed directly thereon in the Z-axis direction) the inactive surface 210w_2.

In an embodiment, the semiconductor substrate 210w may include silicon (Si), for example, crystalline silicon, polycrystalline silicon, or amorphous silicon. Alternatively, the semiconductor substrate 210w may include a semiconductor element such as germanium (Ge) or a compound semiconductor such as silicon carbide (SiC), gallium arsenide (GaAs), indium arsenide (InAs), and indium phosphide (InP). The semiconductor substrate 210w may have a silicon on insulator (SOI) structure. For example, the semiconductor substrate 210w may include a buried oxide (BOX) layer. The semiconductor substrate 210w may include a conductive area, for example, a well that is doped with impurities, or a structure doped with impurities. Also, the semiconductor substrate 210w may have various device isolation structures such as a shallow trench isolation (STI) structure. However, embodiments of the present inventive concept are not necessarily limited thereto.

The first through electrode 220 may pass through the semiconductor substrate 210w in a vertical direction (e.g., the Z-axis direction) and pass through a portion of the semiconductor device layer 210d. In an embodiment, the first through electrode 220 may extend in the vertical direction Z from the active surface 210w_1 to the inactive surface 210w_2. The first through electrode 220 may be electrically connected to connection pads 215 respectively formed on the upper surface and the lower surface of the semiconductor chip 210.

In an embodiment, the semiconductor device layer 210d may include a plurality of semiconductor devices and an interlayer insulating film covering the semiconductor devices. The semiconductor devices may include, for example, switching elements such as transistors.

In some embodiments, a step may be formed on a side surface of the semiconductor chip 210. A horizontal cross-sectional area (e.g., an area in a plane defined in the X-axis and Y-axis directions) of the semiconductor chip 210 may vary as a level thereof in the vertical direction Z changes. In an embodiment, the horizontal cross-sectional area of the semiconductor chip 210 may continuously change as the level thereof in the vertical direction Z increases. For example, in an embodiment the horizontal cross-sectional area of the semiconductor chip 210 may increase as the distance from the semiconductor device layer 210d in the vertical direction Z increases.

In an embodiment, a length of the semiconductor chip 210 in the vertical direction Z may not exceed 20 μm (e.g., is less than or equal to 20 μm). For example, a sum of the lengths of the semiconductor substrate 210w, the passivation layer 210p, and the semiconductor device layer 210d in the vertical direction Z (e.g., vertical lengths) may be less than or equal to 20 μm.

The semiconductor chip 210 including the passivation layer 210p and the first through electrode 220 may be a feature that occurs in a chip having a relatively small thickness in the vertical direction Z.

In an embodiment, the horizontal cross-sectional area of the semiconductor chip 210 may increase as a distance of the semiconductor chip 210 from the semiconductor device layer 210d increases. For example, as shown in an embodiment of FIG. 2A the horizontal cross-sectional area of the semiconductor chip 210 may increase from the semiconductor device layer 210d to the passivation layer 210p. Accordingly, a footprint of a surface of the semiconductor chip 210 adjacent to the inactive surface 210w_2 may be larger than a footprint of a surface thereof adjacent to the active surface 210w_1. This may be understood as a step formed on the side surface of the semiconductor chip 210.

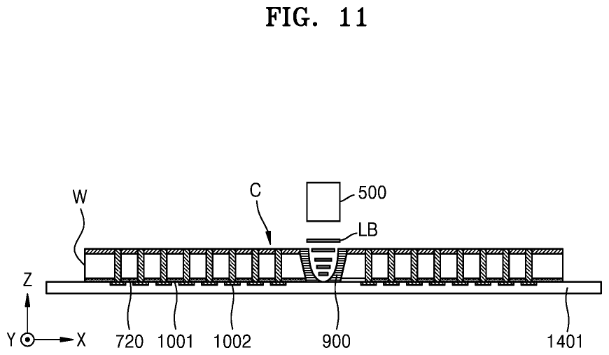

The modified region 290 may be formed on the side surface of the semiconductor chip 210. As described below, the modified region 290 may be a region with deformed properties, formed near a cut surface 280 of the semiconductor substrate 210w as a semiconductor chip (C, see FIG. 11) is sawed by a laser grooving process.

The modified region 290 may be a region in which properties of silicon constituting the semiconductor substrate 210w are modified by heat from laser. The modified region 290 may be formed adjacent to the cut surface 280 of the semiconductor chip 210. In an embodiment, the modified region 290 may be formed over the entire side surface of the semiconductor substrate 210w. For example, the modified region 290 may be formed parallel to the side surface (e.g., a lateral side surface in the X-axis direction) of the semiconductor substrate 210w. As described below, in the semiconductor package 10 according to an embodiment of the present inventive concept, as the semiconductor chip 210 is cut from the wafer W by laser grooving, traces due to laser heat may be generated on the semiconductor chip 210 during a cutting process. The traces may indicate that the semiconductor substrate 210w is deformed by heat. For example, the traces may indicate that silicon of the semiconductor substrate 210w is deformed by heat. In addition, the traces may be understood to be the same as the modified region 290.

In an embodiment, the modified region 290 may have a lower density than other regions of the semiconductor substrate 210w. For example, the density of the modified region may have the lowest density of the entirety of the semiconductor substrate 210w. As the modified region 290 is melted by laser heat and hardened again, the density of the modified region 290 may be lower than before melting. Accordingly, the density of the modified region 290 may be lower than that of all other regions of the semiconductor substrate 210w.

Also, the modified region 290 may be amorphous. The modified region 290 may be a region in which crystal directionality is irregularly changed as silicon of the semiconductor substrate 210w is melted by laser heat and then hardened again.

In addition, as a step is formed on the cut surface 280 of the semiconductor substrate 210w, for example, as a horizontal cross-sectional area of the semiconductor substrate 210w changes as the level of the semiconductor substrate 210w in the vertical direction Z changes, the connection film 270 (see FIG. 1) may be formed in a certain shape, as illustrated in FIG. 1. A space in the vertical direction Z may be formed between the stacked semiconductor chips 210 by the step. In addition, the space may induce an upper or lower flow of the connection film 270 (see FIG. 1) to form the connection film 270 (see FIG. 1) having a certain shape.

FIG. 3A is a schematic cross-sectional view of an embodiment of the semiconductor chip of the semiconductor package of FIG. 1. FIG. 3B is an enlarged view of region BB of FIG. 3A. Hereinafter, repeated descriptions of the details of identical or similar elements of the semiconductor chip 210 provided with reference to FIGS. 2A and 2B and those of a semiconductor chip 210-1 of FIGS. 3A and 3B may be omitted for economy of description, and the description will focus on differences.

Referring to FIGS. 3A and 3B, the semiconductor chip 210-1 may include a semiconductor substrate 210-1w, a semiconductor device layer 210-1d, a passivation layer 210-1p, a connection pad 215, and a modified region 290-1. The semiconductor substrate 210-1w may have an active surface 210-1w_1 and an inactive surface 210-1w_2 opposite to the active surface 210-1w_1 (e.g., in the Z-axis direction). The first through electrode 220 may pass through the semiconductor substrate 210-1w in a vertical direction and pass through a portion of the semiconductor device layer 210-1d.

A side surface of the semiconductor chip 210-1 (e.g., a lateral side surface in the X-axis direction) may have a shape extending in the vertical direction Z. For example, a step may not be formed on the side surface of the semiconductor chip 210-1. As a result, a vertical cross-section of the semiconductor chip 210-1 may have a rectangular shape. In an embodiment in which the vertical cross-section of the semiconductor chip 210-1 has a rectangular shape, warpage may be reduced.

In an embodiment, a wavelength, intensity, waveform, pulse, etc. of a laser beam irradiated during laser grooving may be adjusted so that a step is not formed on the side surface of the semiconductor chip 210-1. For example, by adjusting parameters of a laser beam such that the laser beam is uniformly irradiated onto a wafer, the side surface of the semiconductor chip 210-1 having a rectangular vertical cross-section may be formed.

The modified region 290-1 may be formed on the side surface of the semiconductor chip 210-1. The modified region 290-1 may be a region with modified properties, formed near a cut surface 280-1 of the semiconductor substrate 210-1w.

The modified region 290-1 may be formed in parallel along the side surface of the semiconductor chip 210-1. Accordingly, the modified region 290-1 may also be formed in a rectangular shape.

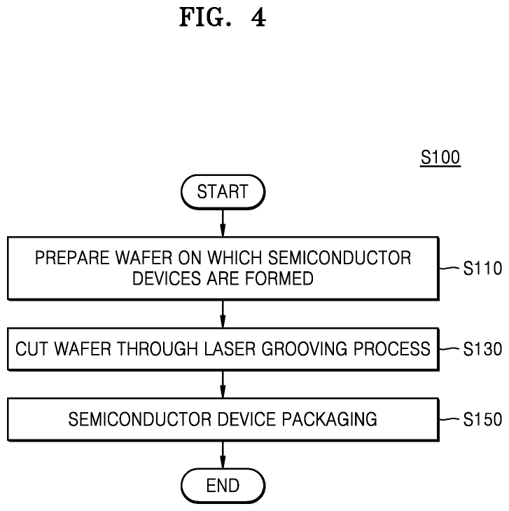

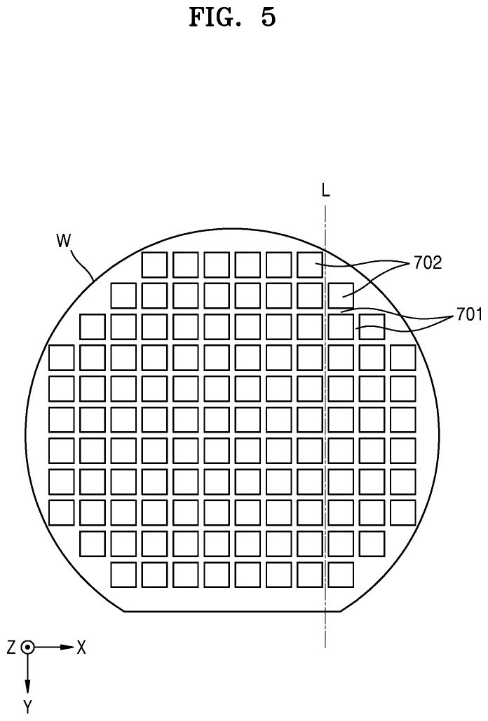

FIG. 4 is a schematic flowchart of a semiconductor package manufacturing method according to embodiments of the present inventive concept. FIGS. 5 to 12 are cross-sectional views for describing a semiconductor package manufacturing method according to embodiments of the present inventive concept.

Hereinafter, the semiconductor package manufacturing method according to embodiments will be described with reference to FIGS. 4 to 12. In addition, descriptions of the details of identical or similar elements provided with reference to FIGS. 1 to 3B may be omitted for economy of description.

Referring to FIGS. 4 to 9, in operation S110, a wafer W is prepared on which semiconductor devices are formed. In an embodiment, the wafer W may include device formation regions on which semiconductor devices are formed, and scribe lanes 701 for separating the device formation regions from each other.

FIG. 5 is a plan view of the wafer W on which semiconductor devices according to an embodiment of the present inventive concept are formed. For example, FIG. 5 is a plan view of a wafer W including a plurality of semiconductor chips C to be stacked in a semiconductor package. In an embodiment, the wafer W may include any one of a wafer substrate, a carrier substrate, and a PCB. The wafer W may include silicon (Si). The wafer W may include a semiconductor element such as germanium (Ge) or a compound semiconductor such as silicon carbide (SiC), gallium arsenide (GaAs), indium arsenide (InAs), and indium phosphide (InP). However, embodiments of the present inventive concept are not necessarily limited thereto.

In an embodiment, the wafer W may have an SOI structure. For example, the wafer W may include a BOX layer formed on the entire surface of the wafer W. In an embodiment, the wafer W may include a conductive region formed on the entire surface of the wafer W, for example, wells doped with impurities. According to an embodiment, the wafer W may have various device isolation structures such as an STI structure that separates the doped wells from each other.

The wafer W may include a plurality of semiconductor chips C forming a semiconductor device layer 702 on an upper surface thereof. In an embodiment, the semiconductor device layer 702 formed on the semiconductor chips C may include a plurality of individual devices of various types.

The individual devices formed on the semiconductor device layer 702 may be any one of a memory device and a non-memory device. In an embodiment, the memory device may include a non-volatile NAND-type flash memory. In an embodiment, the memory device may include PRAM, MRAM, ReRAM, FRAM, NOR flash memory, and the like. However, embodiments of the present inventive concept are not necessarily limited thereto. Also, the memory device may include a volatile memory device that loses data when power thereto is cut off, such as DRAM and SRAM. In an embodiment, the memory device may include a logic chip, a measurement device, a communication device, a digital signal processor (DSP), or a system-on-chip (SoC).

A process of forming a semiconductor device may include: i) performing an oxidation process to form an oxide film; ii) performing a lithography process including spin coating, exposure, and development; iii) performing a thin film deposition process; iv) performing a dry or wet etching process; and v) performing a metal wiring process.

The oxidation process is a process of forming a thin and uniform silicon oxide film through a chemical reaction between oxygen or water vapor with a surface of a silicon substrate at a high temperature in a range of about 800 degrees to about 1200 degrees. The oxidation process may include dry oxidation and wet oxidation. Through the dry oxidation process, an oxide film may be formed by reacting with oxygen gas, and through the wet oxidation process, an oxide film may be formed by making oxygen react with water vapor.

In an embodiment, an SOI structure may be formed on a substrate by an oxidation process. The substrate may also include a BOX layer. In an embodiment, the substrate may have various device isolation structures such as an STI structure.

The lithography process is a process of transferring a circuit pattern previously formed on a lithography mask, to a substrate through exposure. In an embodiment, the lithography process may be performed sequentially by spin coating, exposure, and development processes.

In an embodiment, the thin film deposition process may include one of, for example, atomic layer deposition (ALD), chemical vapor deposition (CVD), plasma-enhanced CVD (PECVD), Metal Organic CVD (MOCVD), physical vapor deposition (PVD), reactive laser deposition, molecular beam epitaxy, and DC magnetron sputtering. However, embodiments of the present inventive concept are not necessarily limited thereto.

In an embodiment, the dry etching process may be, for example, any one of reactive ion etching (RIE), deep RIE (DRIE), ion beam etching (IBE), and Ar milling. However, embodiments of the present inventive concept are not necessarily limited thereto. For example, in an embodiment the dry etching process that may be performed on the wafer W may be atomic layer etching (ALE). In addition, the wet etching process that may be performed on the wafer W may include an etching process of using at least one of Cl₂, HCl, CHF₃, CH₂F₂, CH₃F, H₂, BCL₃, SiCl₄, Br₂, HBr, NF₃, CF₄, C₂F₆, C₄F₈, SFN, O₂, SO₂, and COS as an etchant gas.

The metal wiring process may include a process of forming a conductive wire (e.g., a metal line) to implement a circuit pattern for operation of a semiconductor device. Through the metal wiring process, transmission paths of ground, power, and signals for operating semiconductor devices may be formed. In an embodiment, a metal wiring may include gold, platinum, silver, aluminum, and tungsten. However, embodiments of the present inventive concept are not necessarily limited thereto.

In an embodiment, in a process of forming a semiconductor device, a planarization process such as a chemical mechanical polish (CMP) process, an ion implantation process, and the like may be performed.

The wafer W may include a plurality of semiconductor chips C divided by the scribe lanes 701. The plurality of semiconductor device layers 702 formed on the wafer W may be spaced apart from each other by a certain distance by the scribe lanes 701. The scribe lanes 701 may not include a semiconductor device layer formed therein. As described below, when the wafer W is cut into a plurality of semiconductor chips C, virtual cutting lines L may be formed on the scribe lanes 701.

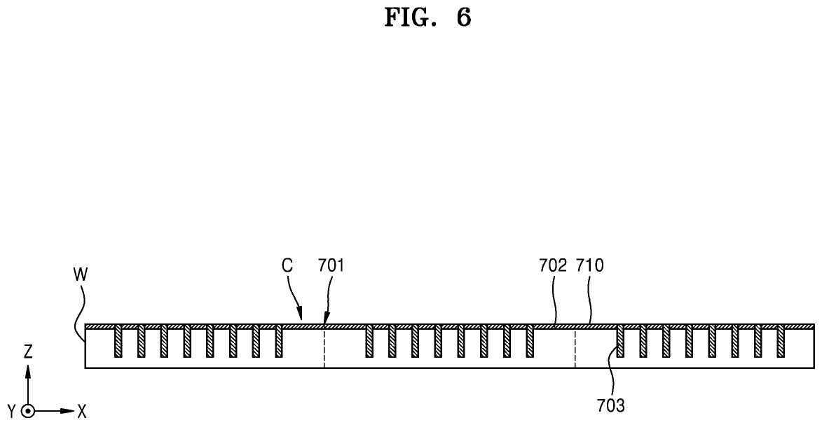

FIG. 6 is a cross-sectional view schematically illustrating that a first through electrode is formed on the wafer W on which semiconductor devices are formed, according to an embodiment of the present inventive concept.

Referring to FIG. 6, operation S110 may further include forming a first through electrode 703 electrically connected to the semiconductor device layer 702. Each of the semiconductor chips C may include the semiconductor device layer 702 and the first through electrode 703. In an embodiment, the first through electrode 703 may extend from an upper surface 710 of the wafer W to the inside of the wafer W. In an embodiment, some of the first through electrodes 703 may have a pillar shape. The first through electrode 703 may include a barrier film formed on a pillar-shaped surface and a buried conductive layer filling the inside of the barrier film. In an embodiment, a via insulating layer may be between the wafer W and the first through electrode 703.

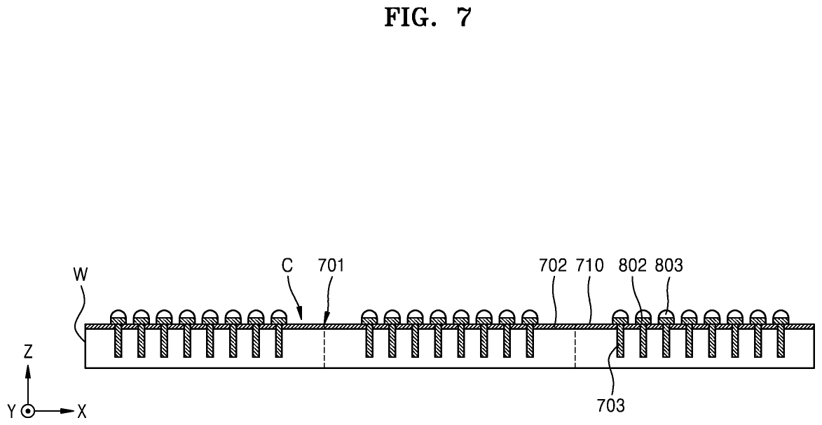

FIG. 7 is a cross-sectional view schematically illustrating first connection pads formed on the wafer W, on which semiconductor devices are formed, according to an embodiment of the present inventive concept. Referring to FIG. 7, operation S110 may further include forming a first connection pad 802 electrically connected to the first through electrode 703. After forming the first connection pad 802, a first connection bump 803 electrically connected to the first through electrode 703 through the first connection pad 802 may be formed on the first connection pad 802 (e.g., formed directly thereon in the Z-axis direction). In an embodiment, the first connection bump 803 may include a pillar structure and a solder layer. In an embodiment, a mask pattern having an opening exposing a portion of the first connection pad 802 may be formed on the semiconductor device layer 702 to form the first connection bump 803. A pillar structure and a solder layer may then be sequentially formed on the portion of the first connection pad 802 exposed by the mask pattern. In an embodiment, the pillar structure and the solder layer may be formed by performing an electroplating process.

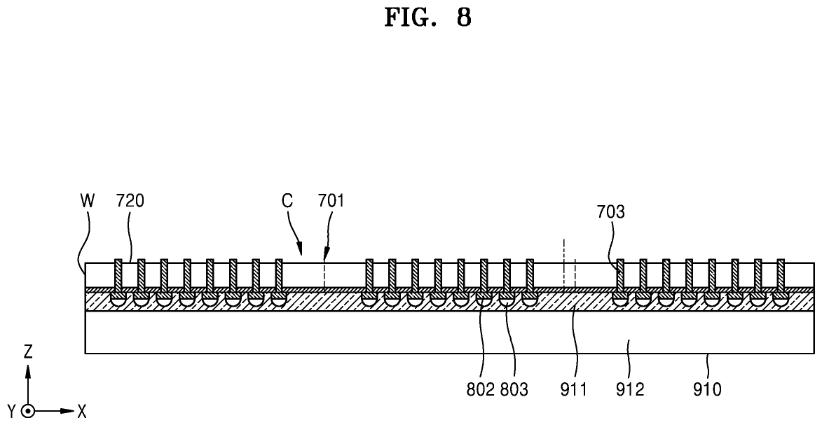

FIG. 8 is a cross-sectional view showing a portion of the first through electrode exposed to the outside by removing a lower surface 720 of the wafer W, on which semiconductor devices are formed, according to an embodiment of the present disclosure. Referring to FIG. 8, a carrier substrate 910 may be attached to the wafer W on the side of the wafer W that the first connection bumps 803 are formed thereon. In an embodiment, the carrier substrate 910 may include a support substrate 912 and an adhesive material layer 911 that is disposed between the support substrate 912 and the wafer W. The wafer W may be attached to the carrier substrate 910 by the adhesive material layer 911 with the first connection bumps 803 facing the carrier substrate 910. In an embodiment, the first connection bumps 803 may be covered by the adhesive material layer 911.

In addition, the first through electrode 703 may be exposed to the outside by partially removing the lower surface 720 of the wafer W. As the first through electrode 703 is exposed on the lower surface 720, the first through electrode 703 may pass through the wafer W. A CMP process, an etch-back process, or a combination thereof may be used to expose the first through electrode 703 to the outside.

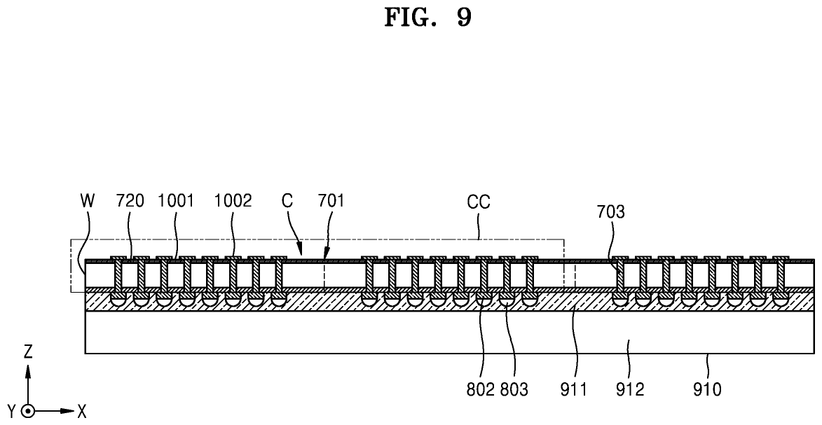

FIG. 9 is a cross-sectional view schematically illustrating a passivation layer and connection pads formed on the wafer W, on which semiconductor devices are formed, according to embodiments.

Referring to FIG. 9, a passivation layer 1001 covering the lower surface 720 of the wafer W may be formed. In an embodiment, the passivation layer 1001 may be formed by, for example, a spin coating process or a spray process. The passivation layer 1001 may include, for example, an insulating polymer. In an embodiment, to form the passivation layer 1001, an insulating polymer film covering the lower surface 720 of the wafer W and the first through electrode 703 exposed to the outside may be formed. The insulating polymer film may then be partially removed through an etch-back process. Through this, the first through electrode 703 may be exposed to the outside.

Also, referring to FIG. 9, after the passivation layer 1001 is formed, a second connection pad 1002 electrically connected to the first through electrode 703 and exposed to the outside through the passivation layer 1001 may be formed.

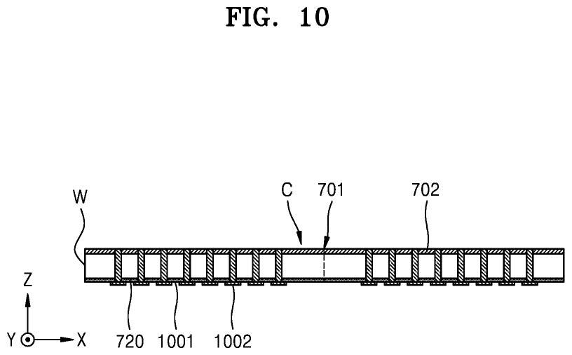

FIG. 10 is an enlarged cross-sectional view obtained by inverting region CC of FIG. 9. When the wafer W is cut on a cutting surface positioned along the scribe lanes 701, the wafer W may be separated into discrete semiconductor chips C. In an embodiment, prior to dicing, the wafer W may be disposed such that the passivation layer 1001 faces downward and the semiconductor device layer 702 faces upward.

FIG. 11 is a cross-sectional view schematically illustrating the cutting of the wafer W through laser grooving. Referring to FIGS. 4 and 11, the wafer W is cut through a laser grooving operation in operation S130.

A method of dicing a wafer by laser grooving may include irradiating a laser beam LB generated by a laser grooving apparatus 500 to a scribe lane. The laser beam LB may have parameters within a range in which the wafer W may be cut. In an embodiment, the parameters may include a pulse, intensity, and wavelength of a laser beam. Accordingly, the wafer W may be cut from an upper surface to a lower surface thereof through the laser beam LB generated by the laser grooving apparatus 500 having a laser.

In the related art, blade dicing, stealth dicing, and the like have been used as wafer dicing methods. When the wafer W is diced through blade dicing and stealth dicing, damage occurs or accuracy decreases when cutting the wafer W having a thickness of less than a certain value.

However, in the wafer dicing method according to an embodiment of the present inventive concept, a thin wafer W may be cut into a plurality of semiconductor chips C through laser grooving. In laser grooving, the wafer W is cut in the vertical direction Z by irradiating a laser and burning the wafer W from the surface of the wafer W. Accordingly, damage occurring to the wafer W during cutting may be prevented, and the dicing accuracy may be increased.

In addition, when cutting the wafer W into semiconductor chips C by laser grooving, the occurrence of chipping is rapidly reduced compared to cutting using a blade, and a modified region distribution layer generated when cutting by stealth dicing may be prevented.

In addition, a shape in which the wafer W is cut may be set by modifying the parameters of the laser beam LB. For example, in an embodiment the wafer W may be cut into a U-shape with a deeply recessed central portion by making a center of the laser beam LB have stronger intensity than the outer portions of the laser beam LB. For example, the horizontal cross-sectional area of the wafer W that is cut by the laser grooving apparatus 500 may increase as the distance to the laser grooving apparatus 500 in which the laser is irradiated increases. However, embodiments of the present inventive concept are not necessarily limited thereto. For example, in an embodiment the wafer W may be cut into a rectangular shape by applying uniform intensity to the entire laser beam LB. In some embodiments, the shape of a cut surface may be various different ones and is not necessarily limited to the above shapes.

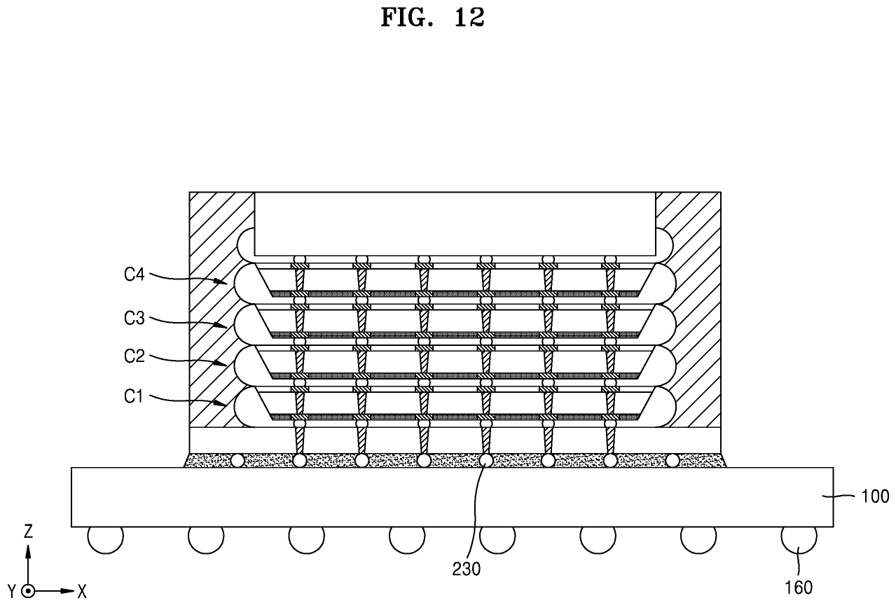

Referring to FIG. 12, in operation S150, the semiconductor devices may be packaged. In an embodiment, a packaging process may include a bonding process, a marking process, a solder ball mount process, a molding process, and the like. However, embodiments of the present inventive concept are not necessarily limited thereto.

Semiconductor chips C1, C2, C3, and C4 cut by laser grooving may be sequentially stacked on the first substrate 100 in the vertical direction Z by a bonding process, a solder ball mount process, or the like. Thereafter, sealing members surrounding the semiconductor chips C1, C2, C3, and C4 may be formed through a molding process to protect the semiconductor chips C1, C2, C3, and C4.

While the present inventive concept has been particularly shown and described with reference to non-limiting embodiments thereof, it will be understood by those of ordinary skill in the art that various changes in form and details may be made therein without departing from the spirit and scope of the present inventive concept.

What is claimed is:

1. A semiconductor chip comprising:
a semiconductor substrate having an active surface and an inactive surface opposite the active surface;
a semiconductor device layer disposed on the active surface; and
a modified region positioned on an entirety of a lateral side surface of the semiconductor substrate.

2. The semiconductor chip of claim 1, wherein the modified region comprises a region that the semiconductor substrate is modified by laser as the semiconductor substrate is cut in a vertical direction by laser grooving.

3. The semiconductor chip of claim 1, wherein the modified region has a lower density than all other regions of the semiconductor substrate.

4. The semiconductor chip of claim 1, wherein the modified region is amorphous.

5. The semiconductor chip of claim 1, wherein a sum of vertical lengths of the semiconductor substrate and the semiconductor device layer is less than or equal to 20 μm.

6. The semiconductor chip of claim 1, wherein a horizontal cross-sectional area of the semiconductor substrate varies as a vertical level of the semiconductor substrate increases.

7. The semiconductor chip of claim 6, wherein a horizontal cross-sectional area of the semiconductor substrate increases as a distance from the semiconductor device layer increases in a vertical direction.

8. The semiconductor chip of claim 1, further comprising:
a first through electrode passing through the semiconductor substrate in a vertical direction;
a first connection pad disposed on the inactive surface and electrically connected to the first through electrode; and
a passivation layer disposed on the inactive surface.

9. The semiconductor chip of claim 8, wherein:
a horizontal cross-sectional area of the semiconductor substrate increases as a distance from the semiconductor device layer increases in the vertical direction; and
a sum of vertical lengths of the semiconductor substrate and the semiconductor device layer is less than or equal to 20 μm.

10. A semiconductor package comprising:
a first substrate;
a first chip structure arranged on the first substrate; and
a first bump structure electrically connecting the first substrate to the first chip structure,
wherein the first chip structure comprises at least one semiconductor chip,
the at least one semiconductor chip comprises a semiconductor substrate and a semiconductor device layer,
a modified region is positioned over an entirety of a lateral side surface of the semiconductor substrate, and
the modified region comprises a region that the semiconductor substrate is modified by laser as the semiconductor substrate is cut in a vertical direction by laser grooving.

11. The semiconductor package of claim 10, wherein:
the at least one semiconductor chip comprises a plurality of semiconductor chips;
the plurality of semiconductor chips are stacked in the vertical direction; and
a horizontal cross-sectional area of each of the plurality of semiconductor chips varies as a vertical level of each semiconductor chip increases.

12. The semiconductor package of claim 11, further comprising a base chip mounted on the first substrate,
wherein the plurality of semiconductor chips is spaced apart from the first substrate in the vertical direction and the base chip is disposed therebetween.

13. The semiconductor package of claim 11, further comprising a connection film disposed between the plurality of semiconductor chips.

14. The semiconductor package of claim 10, wherein the modified region has a lower density than all other regions of the semiconductor substrate.

15. The semiconductor package of claim 10, wherein:
the semiconductor substrate has an active surface and an inactive surface opposite the active surface; and
the semiconductor package further comprises:
a first through electrode passing through the semiconductor substrate in the vertical direction,
a first connection pad disposed on the inactive surface and electrically connected to the first through electrode, and
a passivation layer disposed on the inactive surface.

16. The semiconductor package of claim 10, wherein the modified region is amorphous.

17. The semiconductor package of claim 10, further comprising:
a base chip arranged at a lowermost end of the first chip structure;
wherein a first through electrode is disposed in the at least one semiconductor chip, the first through electrode vertically passes through the semiconductor substrate;
the at least one semiconductor chip comprises a plurality of semiconductor chips, the plurality of semiconductor chips are stacked in the vertical direction, wherein a horizontal cross-sectional area of each of the plurality of semiconductor chips varies as a vertical level of each semiconductor chip increases;
the modified region is arranged in parallel to the lateral side surface of the at least one semiconductor chip;
a density of the modified region is lower than densities of all other regions of the semiconductor substrate; and
the modified region is amorphous.

18. A wafer dicing method comprising:
preparing a wafer having a plurality of device formation regions and a scribe lane region defining the plurality of device formation regions; and
cutting the wafer on a cutting surface of the wafer positioned along the scribe lane region,
wherein the wafer is separated into a plurality of semiconductor chips by a laser grooving process using a laser,
a modified region is formed in the wafer by the laser, and
the modified region is formed over an entirety of the cutting surface of the wafer.

19. The wafer dicing method of claim 18, wherein the wafer comprises a semiconductor substrate, and
the modified region has a lower density than other regions than the modified region, in the semiconductor substrate.

20. The wafer dicing method of claim 18, wherein a horizontal cross-sectional area of the wafer cut by the laser grooving process increases as a distance from the laser increases.
